(19) United States
(12) Patent Application Publication
(10) Pub. No.: US 2010/0059313 A1
(43) Pub. Date: Mar. 11, 2010

(54) LAYOUT STRUCTURE AND METHOD FOR REDUCING AUDIBLE NOISE GENERATED BY FLEXIBLE PRINTED CIRCUIT

(75) Inventors: Chi-Ming Lee, Shulin City (TW); Yu-Ming Su, Sinjhuang City (TW)

Correspondence Address: LIU & LIU, 444 S. FLOWER STREET, SUITE 1750, LOS ANGELES, CA, 90071, US

(73) Assignee: TPO Displays Corp., Chu-Nan (TW)

(21) Appl. No.: 12/553,903

(22) Filed: Sep. 3, 2009

(30) Foreign Application Priority Data
Sep. 3, 2008 (TW) 097133736

(51) Int. Cl. G10K 11/16; H05K 1/00

(52) U.S. Cl. 181/296; 174/254

(57) ABSTRACT

A layout structure and a method for reducing audible noise generated by a flexible printed circuit are provided. The layout structure includes a flexible printed circuit and a piezoelectric element. The flexible printed circuit is disposed with respect to an axis. When an alternating voltage/current is applied across the piezoelectric element, the piezoelectric element expands and contracts alternately. The piezoelectric element is located on the flexible printed circuit, and an angle between the axis and a side of the piezoelectric element is less than 90 degrees.

### CROSS-REFERENCE TO RELATED APPLICATIONS

This application claims priority to Taiwan Patent Application No. 97133736 entitled “LAYOUT STRUCTURE AND METHOD FOR REDUCING AUDIBLE NOISE GENERATED BY FLEXIBLE PRINTED CIRCUIT”, filed on Sep. 3, 2008, which is incorporated herein by reference and assigned to the assignee herein.

### TECHNICAL FIELD

The present invention relates to a structure and a method for reducing audible noise generated by vibration of a flexible printed circuit, and more particular, to a structure and a method for reducing audible noise generated by vibration of a flexible printed circuit caused by piezoelectric effect.

### BACKGROUND

The printed circuit board (PCB) can be used to provide circuit connections between various electronic components. With the development of microminiature and folding design of the electronic equipments, the requirement of the flexible printed circuit (FPC) is growing rapidly due to its properties of ductility, lightness, soft, thinness, and 3D routing capability. Typically, the flexible printed circuit is made of flexible substrate and conductive material, which can be bent or rolled according to the application requirement.

The multi-layer ceramic capacitor (MLCC) is one of common devices used in the flexible printed circuit. FIG. 1 illustrates a prior art structure of a multi-layer ceramic capacitor 120 disposed on a flexible printed circuit 110. As shown in FIG. 1, the multi-layer ceramic capacitor 120, with a lateral length of L, mainly includes two electrodes 140 at both sides and a plurality of ceramic plates 130, wherein the two electrodes 140 are electrically connected to the flexible printed circuit 110 by bonding pads 150. When applying an alternating voltage, the ceramic plates 130 will expand and contract alternately due to piezoelectric effect. Therefore, a periodical deformation in the lateral length of the multi-layer ceramic capacitor 120 will be introduced, for example, the lateral length can vary between L1 and L2 as shown in FIGS. 2A and 2B.

Since the multi-layer ceramic capacitor 120 is fixed on the flexible printed circuit 110 (through the bonding pads 150 in this example), the periodical deformation in the length of the multi-layer ceramic capacitor 120 will drive the flexible printed circuit 110 to vibrate up and down. Regarding to FIGS. 2A and 2B, the vibration amplitude of the flexible printed circuit 110 will vary between v and −v. Typically, the loudness of the sound wave generated by the vibration of the flexible printed circuit increases as the vibration amplitude of the flexible printed circuit increases, such that the audible noise that can be heard by the human ear may be generated.

Therefore, it is desired to have a structure and a method capable of reducing audible noise caused by vibration of the flexible printed circuit.

### SUMMARY

According to one embodiment of the present invention, a layout structure including a flexible printed circuit and a piezoelectric element is provided. The flexible printed circuit is disposed with respect to an axis. The piezoelectric element expands and contracts alternately along a side thereof when being applied with an alternating voltage. The piezoelectric element is located on the flexible printed circuit, and an angle between the side of the piezoelectric element and the axis is less than 90 degrees.

According to another embodiment of the present invention, a method for reducing audible noise generated by vibration of a flexible printed circuit is provided. The flexible printed circuit is disposed with respect to an axis. The method includes the following steps: determining that vibration of the flexible printed circuit is caused by a piezoelectric element located on the flexible printed circuit, the piezoelectric element expanding and contracting alternately along a side of the piezoelectric element when an alternating voltage is applied; and adjusting an angle between the side and the axis to reduce vibration of the flexible printed circuit.

According to still another embodiment of the present invention, a method for reducing audible noise generated by vibration of a flexible printed circuit is provided. The flexible printed circuit is disposed with respect to an axis. The method includes the following steps: determining that vibration of the flexible printed circuit is caused by a piezoelectric element located on the flexible printed circuit, wherein a longitudinal deformation of the piezoelectric element in a side of the piezoelectric element is caused when an alternating voltage is applied on the piezoelectric element; and adjusting a physical parameter of the piezoelectric element to reduce a component of the longitudinal deformation along a direction perpendicular to the axis.

The other aspects of the present invention, part of them will be described in the following description, part of them will be apparent from description, or can be known from the execution of the present invention. The aspects of the invention will be realized and attained by means of the elements and combinations particularly pointed out in the appended claims. It is to be understood that both the foregoing general description and the following detailed description are exemplary and explanatory only and are not restrictive of the invention, as claimed.

### BRIEF DESCRIPTION OF THE DRAWINGS

The present invention will now be further described by way of example only with reference to the accompany drawings in which:

FIG. 1 illustrates exemplary structure of a multi-layer ceramic capacitor disposed on a flexible printed circuit;

FIGS. 2A and 2B are diagrams showing the vibration of the flexible printed circuit caused by the multi-layer ceramic capacitor;

FIGS. 3A and 3B are respectively a top-view and a side-view of a multi-layer ceramic capacitor located on a flexile printed circuit in accordance with one embodiment of the present invention;

FIG. 4 shows a method for reducing vibration of the flexible printed circuit in accordance with one embodiment of the present invention;

FIG. 5 shows a method for reducing vibration of the flexible printed circuit in accordance with another embodiment of the present invention;

FIG. 6 shows a method for reducing vibration of the flexible printed circuit in accordance with still another embodiment of the present invention; and

FIG. 7 is a flowchart of an illustrative method for reducing audible noise generated by vibration of the flexible printed circuit in accordance with one embodiment of the present invention.

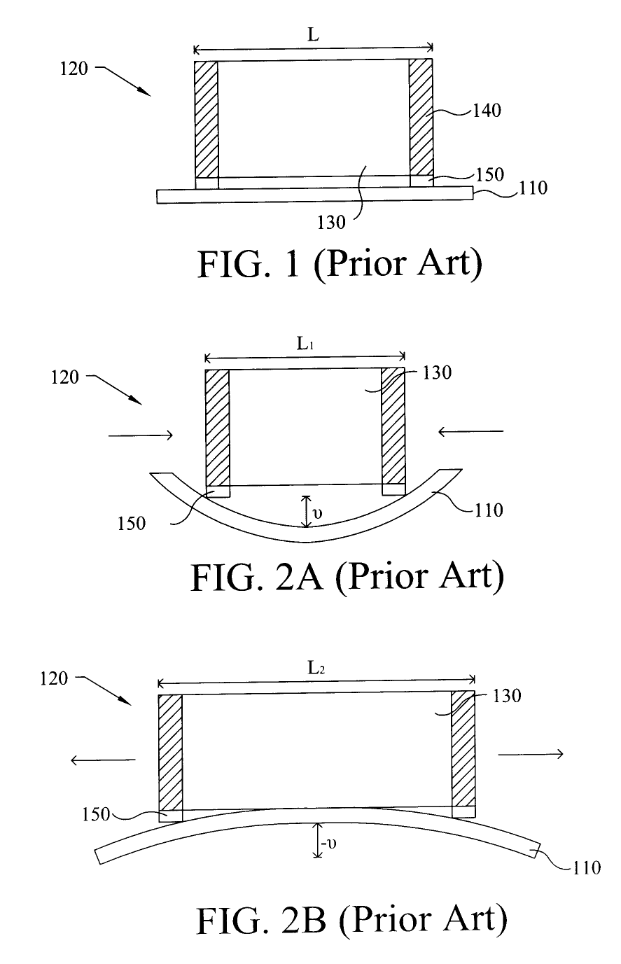

### DETAILED DESCRIPTION OF THE EMBODIMENTS

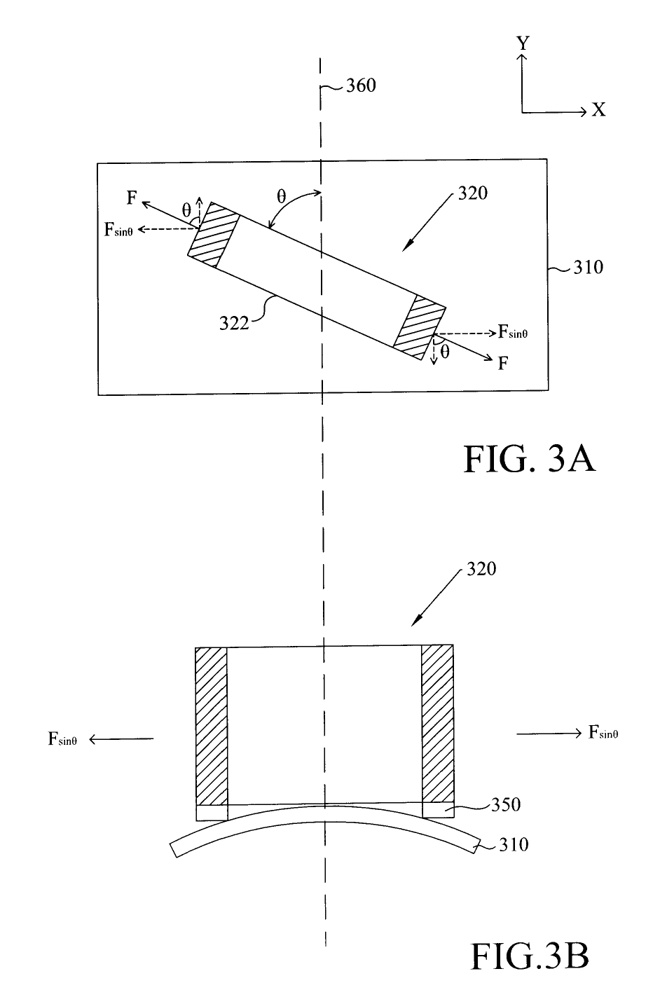

The present invention discloses a layout structure and a method for reducing audible noise generated by a flexible printed circuit by means of adjusting physical characteristics of piezoelectric elements disposed on the flexible printed circuit. The present invention will be described more fully hereinafter with reference to the FIGS. 3A-7. However, the devices, elements, and methods in the following description are configured to illustrate the present invention, and should not be construed in a limiting sense.

FIGS. 3A and 3B are respectively a top-view and a side-view of a multi-layer ceramic capacitor 320 located on a flexile printed circuit 310 according to one embodiment of the present invention. Referring to FIGS. 3A and 3B simultaneously, the flexible printed circuit 310 is disposed with respect to an axis 360, and is bent downward about the axis 360 when being in use (as shown in FIG. 3B). Typically, the magnitude and orientation of curvature of the flexible printed circuit 310 may vary depending on the application requirement. In this embodiment, since the axis 360 is parallel to Y-direction, the flexible printed circuit 310 has higher vibration resistance in Y-direction. In other words, when the flexible printed circuit 310 is bent with respect to the axis 360, it generally becomes difficult to vibrate or be bent with respect to any axis parallel to X-direction. Because the multi-layer ceramic capacitor 320 is made of piezoelectric material, a stress F will be generated when an alternating voltage is applied to the multi-layer ceramic capacitor 320. The stress F makes the multi-layer ceramic capacitor 320 expand and contract periodically according to the frequency of the alternative voltage, such that the length of the side 322 of the multi-layer ceramic capacitor 320 will be accordingly lengthened and shortened periodically. In this embodiment, because the multi-layer ceramic capacitor 320 is fixed on the flexible printed circuit 310 by the bonding pads 350 at a position where the axis 360 passes through, the length variation of the multi-layer ceramic capacitor 320 will drive the flexible printed circuit 310 to vibrate up and down with respect to the axis 360.

In this embodiment, only the force perpendicular to the axis 360 can drive the flexible printed circuit 310 to vibrate with respect to the axis 360, while the force parallel to the axis 360 can be ignored due to the high vibration resistance in Y-direction of the flexible printed circuit 310. In other words, the larger the component of the stress F in X-direction is, the higher the vibration amplitude of the flexible printed circuit 310 is. Therefore, in one embodiment of the present invention, the angle θ between the side 322 of the multi-layer ceramic capacitor 320 and the axis 360 is adjusted to reduce the component of the stress F in X-direction. The component of the stress F along X-direction (F·sin θ) is getting smaller with decreasing angle θ, and accordingly, the force which can drive the flexible printed circuit 310 to vibrate is becoming smaller. Furthermore, the smaller the angle θ is, the smaller the length variation of the side 322 of the multi-layer ceramic capacitor 320 along X-direction is, such that the vibration with respect to the axis 360 caused by the length variation will be reduced. The magnitude of angle θ can vary depending upon requirement, and typically the angle θ is adjusted to make the amplitude of vibration small enough so that there is no perceivable noise. In one embodiment, the multi-layer ceramic capacitor 320 is arranged to make the side 322 parallel to Y-axis (i.e. θ=0) to minimize the vibration of the flexible printed circuit 310.

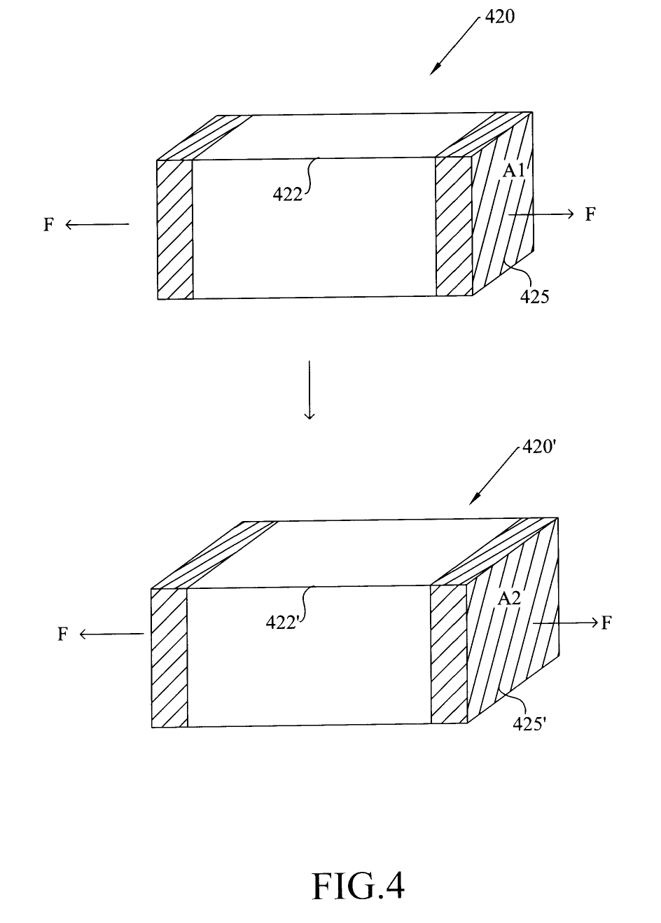

FIG. 4 shows a method for reducing vibration of the flexible printed circuit in accordance with one embodiment of the present invention. In this embodiment, when being subjected to piezoelectric effect, a length of the side 422 of the multi-layer ceramic capacitor 420 will change by a stress F caused by piezoelectric effect. The length change of the side 422 is in proportion to a pressure caused by the stress F, wherein the pressure is the stress F divided by area A1 of the cross-section 425 which is perpendicular to the side 422. As described above, the larger the length variation of the side 422 is, the higher the vibration amplitude of the flexible printed circuit is. Therefore, this embodiment replaces the multi-layer ceramic capacitor 420 with a multi-layer ceramic capacitor 420′, wherein the multi-layer ceramic capacitor 420′ has a cross-section 425′ with a larger area A2 and the same capacitance compared with the multi-layer ceramic capacitor 420 (for example, the material of the multi-layer ceramic capacitor 420′ is different from that of the multi-layer ceramic capacitor 420). Since A2>A1 and (F/A1)>(F/A2), the length variation of the side 422′ is smaller than that of the side 422 under the influence of the stress F. In short, this embodiment reduces the pressure applied on the multi-layer ceramic capacitor by increasing area of the cross-section, which leads to decrease in both length change of the side and the vibration amplitude of the flexible printed circuit.

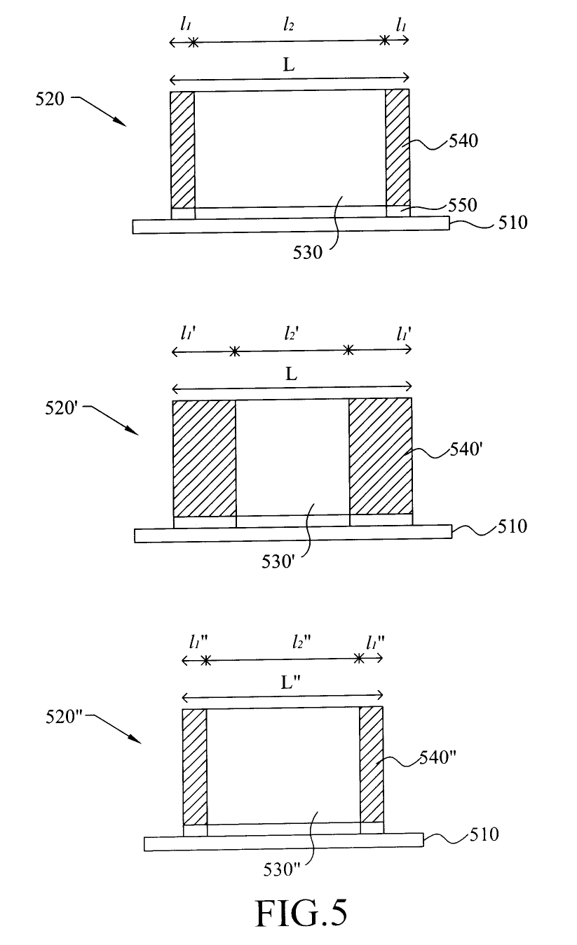

FIG. 5 shows a method for reducing vibration of the flexible printed circuit in accordance with another embodiment of the present invention. In this embodiment, the multi-layer ceramic capacitor 520, which is fixed on the flexible printed circuit 510 by the bonding pads 550, has a side of length L which includes two electrodes 540 of length l₁ and a ceramic plate 530 of length l₂. According to the physical properties of piezoelectric effect, the length change of the ceramic plate 530 caused by the piezoelectric effect is proportional to the length l2 of the ceramic plate 530. Therefore, this embodiment reduces the vibration of the flexible printed circuit 510 by reducing the length of the ceramic plate 530 on the condition that the capacitance of the multi-layer ceramic capacitor 520 keeps unchanging. The manner of reducing the length of the ceramic plate 530 is not limited by the present invention, for example, the length of the electrode 540 can be increased without changing the side length of the capacitor 520. For example, as the multi-layer ceramic capacitor 520′ shown in FIG. 5, the length of the ceramic plate 530′ can be reduced to l₂′ (<l₂) by increasing the length of the electrode 540′ to l₁′ (>l₁) and keeping the side length of the multi-layer ceramic capacitor 520′ the same. In another embodiment, the size of the whole capacitor can be reduced in an equal proportion, as the multi-layer ceramic capacitor 520″ shown in FIG. 5. The lengths of the electrode 540″ and the ceramic plate 530″ are reduced to l₁″ (<l₁) and l₂″ (<l₂) respectively in equal proportion, so the side length of the multi-layer ceramic capacitor 520″ is reduced to L″(<L) accordingly. In a word, this embodiment lessens longitudinal deformation of the ceramic plate by reducing the length of the ceramic plate, and then further lowers the vibration amplitude of the flexible printed circuit.

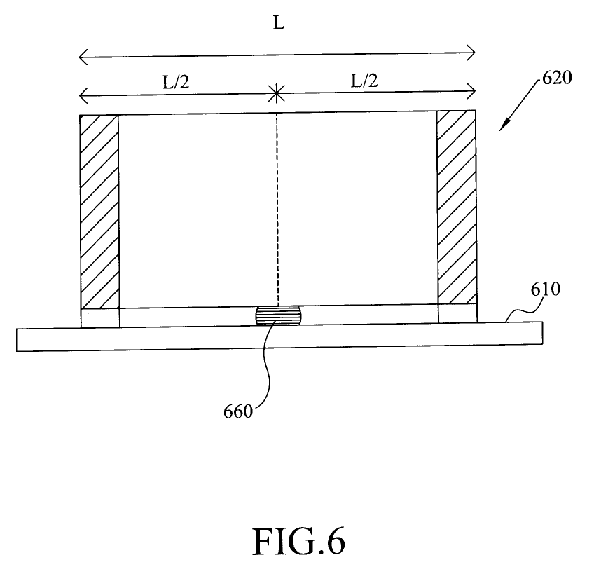

FIG. 6 shows a method for reducing vibration of the flexible printed circuit in accordance with still another embodiment of the present invention. In this embodiment, a buffer pad 660 is disposed between the flexible printed circuit 610 and the multi-layer ceramic capacitor 620 for absorbing vibration. The buffer pad 660 can absorb energy of vibration so that the vibration amplitude of the flexible printed circuit 610 can be reduced. Furthermore, by adding the buffer pad 660, an additional contact point between the flexible printed circuit 610 and the multi-layer ceramic capacitor 620 is introduced. Therefore, referring to FIG. 6, the vibration of the flexible printed circuit 610 is now caused by a longitudinal deformation in a length L/2. Because the magnitude of the deformation is approximately proportional to the length, the deformation in length L/2 is half of that in length L and the vibration amplitude of the flexible printed circuit 610 is decreased accordingly.

In some embodiments, not only the vibration of the flexible printed circuit caused by the multi-layer ceramic capacitor but also any other vibrations of the flexible printed circuit caused by piezoelectric effect can be reduced.

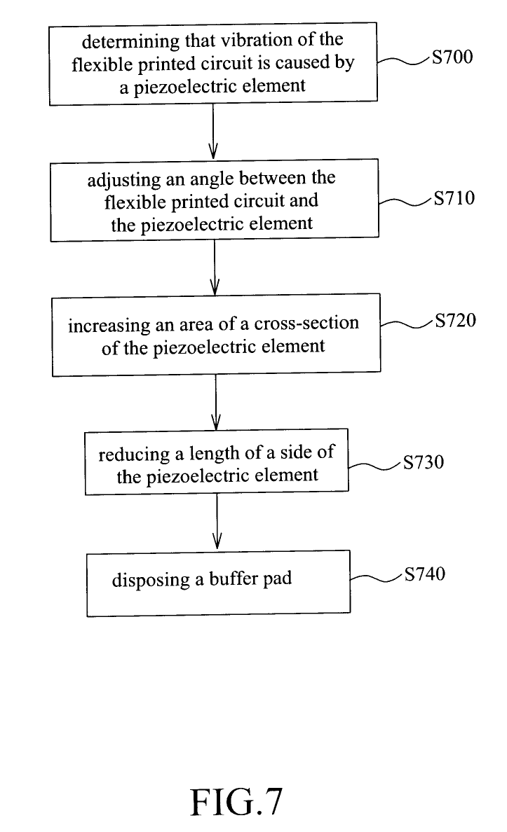

FIG. 7 is a flowchart of an illustrative method for reducing audible noise generated by vibration of a flexible printed circuit in accordance with one embodiment of the present invention. First, in step S700, vibration of the flexible printed circuit is determined to be caused by a piezoelectric element located on the flexible printed circuit. A longitudinal deformation in a side of the piezoelectric element is generated when an alternating voltage is applied to the piezoelectric element. Next, in step S710, an angle between the side of the piezoelectric element and an axis is adjusted to reduce a component of the longitudinal deformation along a direction perpendicular to the axis, wherein the flexible printed circuit is bent with respect to the axis. In step S720, an area of a cross-section which is perpendicular to the side is increased for lowering the longitudinal deformation of the piezoelectric element. In step S730, a length of the side of the piezoelectric element is reduced for lowering the longitudinal deformation of the piezoelectric element. In step S740, a buffer pad is disposed between the flexible printed circuit and the piezoelectric element to absorb vibration for lowering the longitudinal deformation of the piezoelectric element. It should be understood and appreciated that the present invention is not limited by the order of step S710 to step S740, and some steps can even be skipped if not required. For example, if the audio noise generated by the flexible printed circuit is eliminated after performing the step S720, then the steps S710, S730, and S740 can be skipped.

While this invention has been described with reference to the illustrative embodiments, these descriptions should not be construed in a limiting sense. Various modifications of the illustrative embodiment, as well as other embodiments of the invention, will be apparent upon reference to these descriptions. It is therefore contemplated that the appended claims will cover any such modifications or embodiments as falling within the true scope of the invention and its legal equivalents.

We claim:

1. A layout structure, comprising:
a flexible printed circuit (FPC) disposed with respect to an axis; and
a piezoelectric element located on the flexible printed circuit, the piezoelectric element expanding and contracting alternately along a side of the piezoelectric element when an alternating voltage is applied to the piezoelectric element;
wherein an angle between the side and the axis is less than 90 degrees.

2. The layout structure according to claim 1, further comprising a buffer pad disposed between the flexible printed circuit and the piezoelectric element for absorbing vibration.

3. The layout structure to claim 1, wherein the piezoelectric element is a multi-layer ceramic capacitor (MLCC).

4. A method for reducing audible noise generated by vibration of a flexible printed circuit, the flexible printed circuit being disposed with respect to an axis, the method comprising:
determining that vibration of the flexible printed circuit is caused by a piezoelectric element located on the flexible printed circuit, the piezoelectric element expanding and contracting alternately along a side of the piezoelectric element when an alternating voltage is applied to the piezoelectric element; and
adjusting an angle between the side and the axis to reduce vibration of the flexible printed circuit.

5. The method according to claim 4, wherein the piezoelectric element is a multi-layer ceramic capacitor (MLCC).

6. The method according to claim 5, further comprising a step of increasing an area of a cross-section of the multi-layer ceramic capacitor and keeping a capacitance of the multi-layer ceramic capacitor the same, wherein the cross-section is perpendicular to the side.

7. The method according to claim 5, further comprising a step of reducing a length of the side of the multi-layer ceramic capacitor and keeping a capacitance of the multi-layer ceramic capacitor the same.

8. The method according to claim 5, further comprising a step of disposing a buffer pad disposed between the flexible printed circuit and the piezoelectric element for vibration.

9. A method for reducing audible noise generated by vibration of a flexible printed circuit, the flexible printed circuit disposed with respect to an axis, the method comprising:
determining that vibration of the flexible printed circuit is caused by a piezoelectric element located on the flexible printed circuit, the piezoelectric element having a side, wherein a longitudinal deformation of the piezoelectric element in the side is generated when an alternating voltage is applied on the piezoelectric element; and
adjusting a physical parameter of the piezoelectric element to reduce a component of the longitudinal deformation along a direction perpendicular to the axis.

10. The method according to claim 9, further comprising a step of disposing a buffer pad between the flexible printed circuit and the piezoelectric element for absorbing vibration.

11. The method according to claim 9, wherein the physical parameter is an angle between the side of the piezoelectric element and the axis.

12. The method according to claim 9, wherein the physical parameter is an area of a cross-section perpendicular to the side, and the step of adjusting the physical parameter is to increase the area.

13. The method according to claim 9, wherein the physical parameter is a length of the side, and the step of adjusting the physical parameter is to reduce the length.
